(19) United States
(12) Patent Application Publication
(10) Pub. No.: US 2010/0295076 A1
(43) Pub. Date: Nov. 25, 2010

(54) Semiconductor Component Emitting Polarized Radiation

(76) Inventors: Ralph Wirth, Mintraching-Auhof (DE); Julius Muschaweck, Gauting (DE)

Correspondence Address: SLATER & MATSIL, L.L.P., 17950 PRESTON RD, SUITE 1000, DALLAS, TX, 75252-5793, US

(21) Appl. No.: 12/747,091

(22) PCT Filed: Dec. 12, 2008
(86) PCT No.: PCT/DE08/02079

§ 371 Date: Jul. 21, 2010

(30) Foreign Application Priority Data
Dec. 14, 2007 (DE) 10 2007 060 202.4

(51) Int. Cl. H01L 33/58

(52) U.S. Cl. 257/98; 257/E33.067

(57) ABSTRACT

A semiconductor component emits polarized radiation with a first polarization direction. The semiconductor component includes a chip housing, a semiconductor chip and a chip-remote polarizing filter.

This patent application is a national phase filing under section 371 of PCT/DE2008/002079, filed Dec. 12, 2008, which claims the priority of German patent application 10 2007 060 202.4, filed Dec. 14, 2007, which is incorporated herein by reference in its entirety.

### TECHNICAL FIELD

The invention relates to a semiconductor component which emits polarized radiation with a first polarization direction.

### BACKGROUND

Radiation-emitting semiconductor components such as, for example, light-emitting diodes are advantageous light sources due to their compact size and efficiency. However, the radiation generated is generally unpolarized as a result of spontaneous emission. However, applications such as, for example, LCD backlighting require polarized radiation. With conventional optical systems the radiation generated by the light-emitting diodes is therefore polarized by an external polarizing filter arranged downstream of the light-emitting diodes. However, this makes a compact structure difficult. In addition, with these systems the radiation which does not pass through is typically lost, i.e., it is not put to further use in the system, meaning that the efficiency of the system suffers.

### SUMMARY

In one aspect, the present invention is to provide a semiconductor component which efficiently generates polarized radiation.

According to a preferred embodiment of the invention, the semiconductor component, which emits polarized radiation with a first polarization direction, comprises a chip housing, a semiconductor chip, which is arranged in the chip housing and generates unpolarized radiation, and a chip-remote polarizing filter incorporated into the chip housing, which polarizing filter is arranged downstream of the semiconductor chip in a preferred direction and subdivides the radiation emitted by the semiconductor chip into a first radiation fraction with the first polarization direction and a second radiation fraction with a second polarization direction, the chip-remote polarizing filter having higher transmittance for the first radiation fraction than for the second radiation fraction.

Preferably, the first radiation fraction is transmitted predominantly through the chip-remote polarizing filter, while the second radiation fraction is for the most part reflected at the chip-remote polarizing filter. In particular, after reflection at the chip-remote polarizing filter the reflected second radiation fraction re-enters the chip housing. Reflection processes may take place there, or absorption and re-emission processes may occur in the semiconductor chip, which lead to recovery of the reflected second radiation fraction. Over the course of these processes, a change in polarization direction is possible, such that a part of the reflected second radiation fraction then has the first polarization direction. A light beam thus circulates in the semiconductor component or in the chip housing ideally until it impinges with the first polarization direction on the polarizing filter and may couple out. Or the light beam is absorbed by the semiconductor chip and re-emitted with the first polarization direction and may thus couple out.

In comparison with a conventional optical system with a radiation-emitting semiconductor component and an external polarizing filter, the present semiconductor component makes it possible to increase efficiency, since the reflected second radiation fraction may be recovered.

This also applies to another embodiment of the invention, in which a chip-adjacent polarizing filter is arranged on a surface of the semiconductor chip facing the chip-remote polarizing filter, the chip-adjacent polarizing filter having a higher transmittance for the first radiation fraction than for the second radiation fraction. By means of the chip-adjacent polarizing filter, a first filtering may thus take place, the first radiation fraction preferably being transmitted predominantly through the chip-adjacent polarizing filter while the second radiation fraction is for the most part reflected at the chip-adjacent polarizing filter back into the semiconductor chip and may there be recovered by absorption and re-emission.

The transmitted radiation fraction impinges on the chip-remote polarizing filter and is filtered there, wherein the same processes may take place as already described above.

In this embodiment the semiconductor component may advantageously emit more polarized radiation than in the embodiments with just one polarizing filter. Production is more complex, however, since the smaller chip-adjacent polarizing filter is more difficult to produce than the chip-remote larger polarizing filter.

“Chip-remote” may here be understood to mean that the polarizing filter does not directly adjoin the semiconductor chip. Accordingly, “chip-adjacent” means that the polarizing filter does adjoin the semiconductor chip.

The semiconductor chip is here, in particular, formed from a layer stack of epitaxially grown semiconductor layers, the layer stack comprising an active zone for generating radiation of the wavelength λ.

The active zone comprises a radiation-generating pn-junction. In the simplest case, this pn-junction may be formed by means of a p-conducting and an n-conducting semiconductor layer, which directly adjoin one another. The actual radiation-generating layer may however be arranged between the p-conducting and n-conducting semiconductor layers, for instance in the form of a doped or undoped quantum layer. The quantum layer may take the form of a single quantum well structure (SQW) or multiple quantum well structure (MQW) or indeed of a quantum wire or quantum dot structure.

According to a preferred configuration, the layer stack of the semiconductor chip contains a nitride compound semiconductor, i.e., the layer stack comprises, in particular, AlₓGa_{y}In_{1-x-y}N, wherein 0≦x≦1, 0≦y≦1 and x+y≦1. This material does not absolutely have to exhibit a mathematically exact composition according to the above formula. Instead, it may comprise one or more dopants and additional constituents which do not substantially modify the characteristic physical properties of the AlₓGa_{y}In_{1-x-y}N material. For simplicity's sake, however, the above formula includes only the fundamental constituents of the crystal grid (Al, Ga, In, N), even if these may in part be replaced by small quantities of further substances.

According to a preferred configuration the chip-remote and/or the chip-adjacent polarizing filter may comprise a metal grid. Preferably, the metal grid is formed of metal strips, which extend parallel to one another. Light beams which comprise a polarization direction parallel to the metal strips are then reflected, while light beams which comprise a polarization direction perpendicular to the metal strips are transmitted. In this case the first polarization direction thus corresponds to the polarization direction perpendicular to the metal strips and the second polarization direction corresponds to the polarization direction parallel to the metal strips.

It is however also possible for the purposes of the invention for the first polarization direction to correspond to the parallel polarization direction and the second polarization direction to correspond to the perpendicular polarization direction.

The metal strips of the metal grid are preferably arranged at a distance from one another which is less than the wavelength λ. The width of the metal strips should constitute a fraction of this distance. Such small structures may be produced, for example, by lithographic methods or an imprint method.

In the case of the chip-adjacent polarizing filter, the metal strips may be applied directly to the surface of the semiconductor chip. In the case of the chip-remote polarizing filter it is conceivable for the metal strips to be applied to a support, for example, a plastics foil or a glass substrate, and for the latter to be attached to the chip housing.

In a further embodiment, the polarizing filter takes the form of a birefringent multilayer filter. This comprises, in particular, at least a first birefringent layer with a first refractive index n1 and a second refractive index n and at least a second birefringent layer with a third refractive index n2 and the second refractive index n. The second layer is preferably arranged downstream of the first layer in the beam direction. Particularly preferably, the first and second layers comprise an optical thickness of λ/4.

The birefringent property of the layers may be produced, for example, by applying tension to the layers. In particular the layers may be drawn in a specific direction. The layers preferably contain a plastics material.

According to an advantageous variant, the polarizing filter is a foil, which in particular, contains a plastics material. The foil is easy to handle and may be simply incorporated into the chip housing.

In an advantageous further development the chip housing comprises a recess, which is defined by a bottom surface, on which the semiconductor chip is mounted, and at least one side surface. Preferably at least the side surface is reflective, i.e., it has an advantageously high reflectance. In addition, the bottom surface may also be reflective. As a result of the advantageously high reflectance, a large part of the second radiation fraction reflected at the chip-remote polarizing filter may be recovered, i.e., by reflections in the chip housing or absorption and re-emission processes in the semiconductor chip a part of the reflected second radiation fraction may change polarization direction and couple out.

Furthermore a symmetrical shape, for example, a rotationally or axially symmetrical shape, is advantageous for the recess. In this way multiple reflections suitable for changing the polarization direction may occur. As will be explained in still greater detail in connection with FIG. 4, more than two reflections at the chip housing are particularly favorable, in order to achieve a change in polarization direction.

According to a preferred configuration, the side surface is covered at least partially by a reflective layer. The bottom surface may also be at least partially covered by a reflective layer. The reflective layer is a metallic layer, for example. Comparatively high reflectance may be achieved by means of a metallic layer.

The side surface may be smooth, i.e., it only has roughness features which are small relative to the wavelength λ. In this way, specular reflection may take place, i.e., the angle of incidence of an incident light beam and the reflection angle are of equal size, relative to the normal at the point of incidence.

It is however also possible for the side surface to comprise unevennesses which are large relative to the wavelength λ. In particular, the side surface is roughened by means of the unevennesses in such a way that smooth sub-surfaces form which extend obliquely relative to one another and act as mirror surfaces. The side surface thus preferably comprises a surface structure which is formed from sub-surfaces extending obliquely to one another, which act as mirror surfaces. Polarization mixing of the second radiation fraction reflected at the chip-remote polarizing filter may advantageously be improved by such a surface structure.

In one advantageous embodiment the chip-remote polarizing filter covers the recess. The chip-remote polarizing filter may be arranged for this purpose, in particular, on the chip housing. The polarizing filter may either rest on the chip housing and cover the recess or be arranged with a perfect fit in the recess, for example, on a filling composition. The polarizing filter may then serve as a cover to protect the semiconductor chip, for example, from external influences. The polarizing filter is incorporated into the chip housing both by arrangement of the chip-remote polarizing filter on the chip housing and by arrangement in the recess.

A filling composition may furthermore be arranged in the recess between the chip-remote polarizing filter and the semiconductor chip. The filling composition preferably fills the recess completely. A filling composition is typically used to protect the semiconductor chip from external influences such as the penetration of moisture, dust, foreign bodies, water etc.

The filling composition may, for example, comprise a filling material which contains an epoxy resin or a silicone. By means of such a filling material, the refractive index jump between the semiconductor chip and the surrounding environment may additionally be reduced, such that smaller radiation losses arise as a result of total reflections at the junction between the semiconductor chip and the surrounding environment. Furthermore, the surface of the filling composition may form a suitable bearing surface for the polarizing filter.

A semiconductor chip is preferably used here which is produced by the thin-film method. When producing the thin-film semiconductor chip the layer stack is initially grown epitaxially on a growth substrate. Then a support is applied to an opposite surface of the layer stack from the growth substrate and the growth substrate is subsequently detached. Since the growth substrates used in particular for nitride compound semiconductors, for example, SiC, sapphire or GaN, are comparatively expensive, this method offers, in particular, the advantage that the growth substrate may be reused.

The thin film semiconductor chip is a Lambertian radiation emitter with advantageously increased outcoupling efficiency.

### BRIEF DESCRIPTION OF THE DRAWINGS

Further features, advantages and further developments of the invention are revealed by the exemplary embodiments explained below in conjunction with FIGS. 1 to 4, in which:

FIG. 1 is a schematic cross-sectional view of a first exemplary embodiment of a semiconductor component according to the invention;

FIG. 2 is a schematic cross-sectional view of a second exemplary embodiment of a semiconductor component according to the invention;

FIG. 3 is a schematic cross-sectional view of a third exemplary embodiment of a semiconductor component according to the invention; and

FIGS. 4A and 4B are an illustration of multiple reflections at mirror surfaces.

### DETAILED DESCRIPTION OF ILLUSTRATIVE EMBODIMENTS

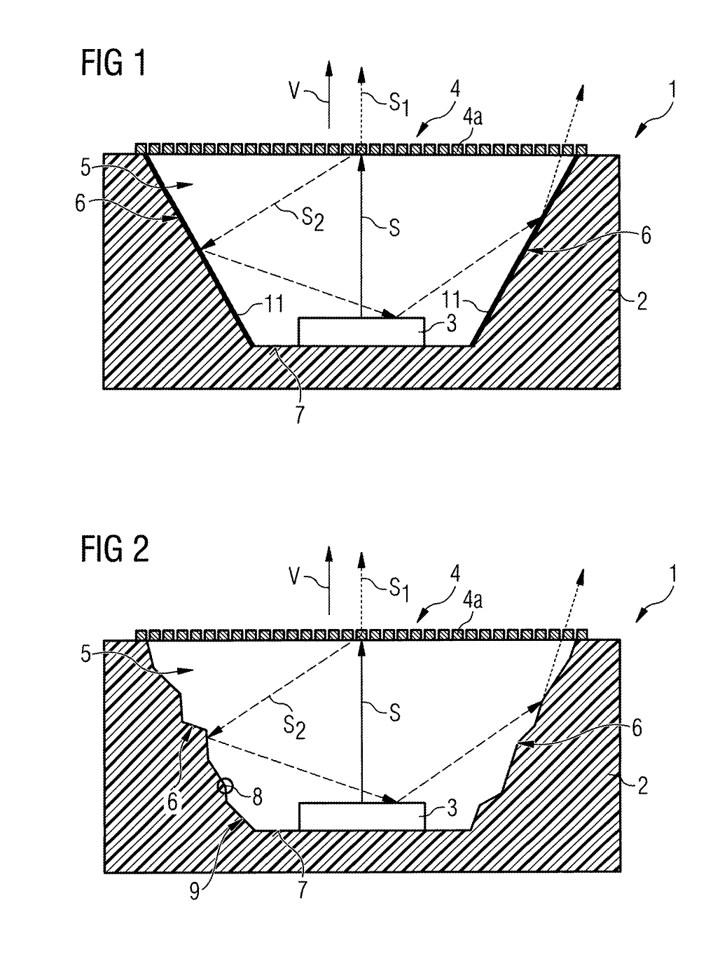

The semiconductor component 1 illustrated in FIG. 1 comprises a chip housing 2 and a semiconductor chip 3, which is arranged in the chip housing 2. A chip-remote polarizing filter 4 is arranged on the chip housing 2, which filter covers a recess 5 in the chip housing 2. The chip-remote polarizing filter 4 is incorporated into the chip housing 2.

In this embodiment the polarizing filter 4 comprises a metal grid, which consists of metal strips 4a, which extend parallel to one another.

The semiconductor chip 3 is arranged in the recess 5 in the chip housing 2. The semiconductor chip 3 is preferably embedded in a filling composition, which fills the recess 5 completely. The filling composition, in particular, contains a radiation-transmissive filling material. The filling material may be a silicone or an epoxy resin, for example.

The recess 5 is defined by an internal side surface 6 and an internal bottom surface 7 of the chip housing 2. In this exemplary embodiment the recess 5 is axially symmetrical in shape, namely it has the shape of a truncated cone tapering in the direction of the semiconductor chip 3. The side surface 6 thus corresponds to the circumferential surface of a truncated cone. The axial symmetry relates to a preferred direction V. The recess 5 may also be provided with a rotationally symmetrical shape, such that the recess 5 has more than one side surface 6.

The preferred direction V is at the same time the direction in which a large part of the radiation coming from the semiconductor component 1 is emitted.

The side surface 6 is preferably reflective and therefore serves as a reflector. In addition, the bottom surface 7 may also be reflective and form the reflector together with the side surface 6. To improve reflectance, the side surface 6 may, in particular, be covered with a reflective layer 11. A metallic layer is suitable therefore, for example.

In the exemplary embodiment illustrated, the side surface 6 is smooth, i.e., it only has roughness features which are small relative to the wavelength λ. In this way, specular reflection may take place, i.e., the angle of incidence of an incident light beam and the reflection angle are of equal size, relative to the normal at the point of incidence.

The semiconductor chip 3, which is, in particular, a thin film semiconductor chip, generates unpolarized radiation S, which impinges on the polarizing filter 4 in the preferred direction V. The polarizing filter 4 subdivides the unpolarized radiation S into a first radiation fraction S1 with a first polarization direction and a second radiation fraction S2 with a second polarization direction, the chip-remote polarizing filter 4 having a higher transmittance for the first radiation fraction S1 than for the second radiation fraction S2.

The first radiation fraction S1 is thus predominantly transmitted, while the second radiation fraction S2 is for the most part reflected. In this way, the semiconductor component 1 all in all emits polarized radiation with the first polarization direction.

After reflection at the chip-remote polarizing filter 4, the reflected second radiation fraction S2 returns to the chip housing 2. Reflection processes may take place therein, or absorption and re-emission processes may occur in the semiconductor chip 3. Over the course of these processes, a change in polarization direction is possible, such that a part of the reflected second radiation fraction S2 then has the first polarization direction and may couple out from the semiconductor component 1.

As is illustrated by the broken-line arrows, a light beam with the second polarization direction reflected at the polarizing filter 4 and circulating in the chip housing 2 may change its polarization direction after more than two reflections, such that it has the first polarization direction. When the light beam again impinges on the polarizing filter 4, it may then couple out of the semiconductor component 1. The light beam may also be absorbed by the semiconductor chip 3 and be re-emitted with the first polarization direction and thus coupled out (not shown).

As has already been mentioned, the polarizing filter 4 comprises a metal grid. Light beams which comprise a polarization direction parallel to the metal strips 4a are in this case reflected, while light beams which comprise a polarization direction perpendicular to the metal strips 4a are transmitted. In this case the first polarization direction thus corresponds to the polarization direction perpendicular to the metal strips 4a and the second polarization direction corresponds to the polarization direction parallel to the metal strips 4a.

The efficiency of the present semiconductor component 1 compared with a conventional optical system in which an external polarizing filter is used is demonstrated below.

The semiconductor chip 3 comprises a diffuse reflectance of 50% and a size of 0.5 mm×0.5 mm×0.2 mm. A refractive index of 1.5 applies to the filling composition. A reflectance of 90% is provided for the side surface 6. The diameter of the bottom surface 7 amounts to 1.8 mm and the diameter of the recess 5 on the radiation exit side amounts to 3 mm. The chip housing 2 has an average height of approx. 1.5 mm. The transmittance of the polarizing filter 4 amounts to 50%.

It is assumed that without a polarizing filter 4 approximately 80.5% of the radiation S generated by the semiconductor chip 3 couples out of the semiconductor component 1. Since the transmittance of the polarizing filter 4 amounts to 50%, with the polarizing filter 4 half of the radiation S, i.e., approximately. 40.3%, is consequently returned into the chip housing 2. By reflection processes and absorption and re-emission processes, the outcoupling efficiency of the semiconductor component 1 may be increased to an average of 52%. In a conventional optical system, however, the reflected radiation fraction is not used again. Thus, 40.3% is lost, and efficiency likewise amounts to only 40.3%. Efficiency may thus be increased with the present semiconductor component 1 by approximately. 29% relative to the conventional optical system.

The semiconductor component 1 illustrated in FIG. 2 has substantially the same structure as the semiconductor component 1 of FIG. 1. The difference lies merely in the surface structure of the side surface 6. The side surface 6 comprises unevennesses 8, which are large relative to the wavelength λ. In particular, the side surface 6 is roughened by means of the unevennesses 8 in such a way that smooth sub-surfaces 9 form which extend obliquely relative to one another and act as mirror surfaces. The side surface 6 thus comprises a surface structure which is formed from smooth sub-surfaces 9 extending obliquely relative to one another, which act as mirror surfaces. In the second exemplary embodiment an outcoupling efficiency of approximately 44.6% may be achieved, which thus lies below the outcoupling efficiency of approximately. 52% achievable with the first exemplary embodiment. Polarization mixing of the second radiation fraction S2 reflected at the chip-remote polarizing filter 4 may advantageously be improved by such unevennesses 8, however.

For recovery of the second radiation fraction S2, however, a side surface with unevennesses as in the second exemplary embodiment appears to have a positive effect, since the efficiency increase achievable by recovery in the second exemplary embodiment amounts to approximately. 28% and thus is virtually as great as the 29% achieved with the first exemplary embodiment.

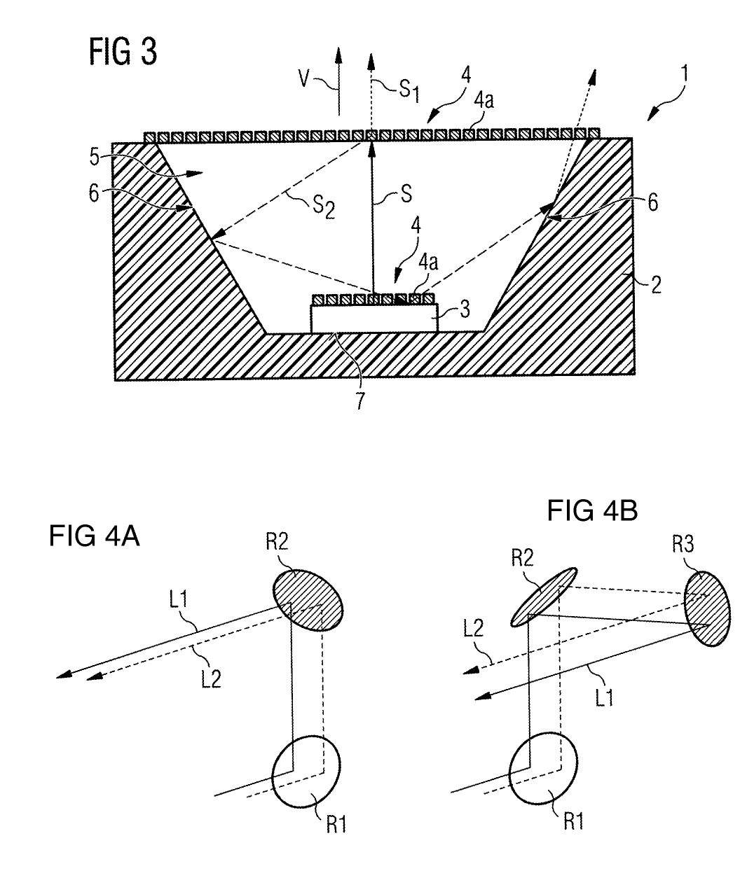

FIG. 3 shows a further embodiment of a semiconductor component 1 according to the invention. This semiconductor component 1 is also constructed substantially like the semiconductor component 1 of FIG. 1. However, the semiconductor component 1 illustrated in FIG. 3 additionally comprises a chip-adjacent polarizing filter 4. In this embodiment the chip-adjacent polarizing filter 4, like the chip-remote polarizing filter 4, comprises a metal grid with metal strips 4a extending parallel to one another. Thus the chip-adjacent polarizing filter 4 functions in the same way as the chip-remote polarizing filter 4.

In the case of the chip-adjacent polarizing filter 4, the metal strips 4a may be applied directly to the surface of the semiconductor chip 3. In the case of the chip-remote polarizing filter 4, use of a foil which comprises the metal strips 4a is advantageous. The foil is arranged on the chip housing 2 and may, for example, be adhesively bonded thereto.

First filtering may take place by means of the chip-adjacent polarizing filter 4, wherein preferably the first radiation fraction S1 is predominantly transmitted by the chip-adjacent polarizing filter 4 while the second radiation fraction S2 is for the most part reflected by the chip-adjacent polarizing filter 4 (not shown). The radiation fraction transmitted by the chip-adjacent polarizing filter 4 is refiltered in the manner already described by the chip-remote polarizing filter 4. Advantageously in this embodiment the semiconductor component 1 may emit more polarized radiation than in the embodiments with just one polarizing filter. Production is more complex, however, since the smaller chip-adjacent polarizing filter 4 is more difficult to produce than the chip-remote larger polarizing filter 4.

It should be noted that the polarizing filters 4 of the embodiments illustrated in FIGS. 1 to 3 do not have to comprise metal grids. The polarizing filters 4 may, for example, also be birefringent multilayer filters or other types of polarizing filter.

FIG. 4A shows a case in which two light beams L1 and L2 are reflected in the chip housing at two mirror surfaces R1 and R2, which may, for example, belong to the side surface. In this case the polarization direction does not change: the polarization directions of the incident and emergent light beams L1 and L2 extend parallel to one another.

In contrast, the polarization direction of the two light beams L1 and L2 changes, as shown in FIG. 4B, if they are reflected in the chip housing at three mirror surfaces R1, R2 and R3, which may, for example, belong to the side surface. The polarization directions of the incident and emergent light beams L1 and L2 extend perpendicularly to one another.

The invention is not restricted by the description given with reference to the exemplary embodiments. Rather, the invention encompasses any novel feature and any combination of features, including in particular any combination of features in the claims, even if this feature or this combination is not itself explicitly indicated in the claims or exemplary embodiments.

1. A semiconductor component which emits polarized radiation with a first polarization direction, the semiconductor component comprising:
a chip housing,
a semiconductor chip arranged in the chip housing, the semiconductor chip capable of generating unpolarized radiation,
a chip-remote polarizing filter incorporated into the chip housing, wherein the filter is arranged downstream of the semiconductor chip in a preferred direction and configured to subdivide the unpolarized radiation emitted by the semiconductor chip into a first radiation fraction with the first polarization direction and a second radiation fraction with a second polarization direction,
the chip-remote polarizing filter having a higher transmittance for the first radiation fraction than for the second radiation fraction.

2. The semiconductor component according to claim 1, further comprising a chip-adjacent polarizing filter arranged adjacent a surface of the semiconductor chip facing the chip-remote polarizing filter, the chip-adjacent polarizing filter having a higher transmittance for the first radiation fraction than for the second radiation fraction.

3. The semiconductor component according to claim 1, wherein the chip-remote polarizing filter comprises a metal grid.

4. The semiconductor component according to claim 3, wherein the metal grid comprises metal strips that extend parallel to one another.

5. The semiconductor component according to claim 1, wherein the chip-remote polarizing filter comprises a birefringent multilayer filter that comprises at least a first birefringent layer with a first refractive index n1 and a second refractive index n and at least a second birefringent layer with a third refractive index n2 and the second refractive index n.

6. The semiconductor component according to claim 1, wherein the chip housing comprises a recess, which is defined by a bottom surface, on which the semiconductor chip is mounted, and at least one reflective side surface.

7. The semiconductor component according to claim 6, wherein the at least one side surface is covered at least in part by a reflective layer.

8. The semiconductor component according to claim 6, wherein the at least one side surface is smooth.

9. The semiconductor component according to claim 6, wherein the at least one side surface comprises unevennesses.

10. The semiconductor component according to claim 9, wherein the at least one side surface comprises a surface structure that is formed from sub-surfaces extending obliquely relative to one another, the sub-surfaces acting as mirror surfaces.

11. The semiconductor component according to claim 6, wherein the chip-remote polarizing filter covers the recess.

12. The semiconductor component according to claim 6, further comprising a filling composition arranged in the recess between the chip-remote polarizing filter and the semiconductor chip.

13. The semiconductor component according to claim 12, wherein the filling composition comprises a filling material that contains an epoxy resin.

14. The semiconductor component according to claim 12, wherein the filling composition comprises a filling material that contains a silicone.

15. The semiconductor component according to claim 2, wherein the chip-adjacent polarizing filter comprises a metal grid.

16. The semiconductor component according to claim 3, wherein the chip-adjacent polarizing filter comprises a metal grid.

17. The semiconductor component according to claim 2, wherein the chip-adjacent polarizing filter comprises a birefringent multilayer filter that comprises at least a first birefringent layer with a first refractive index n1 and a second refractive index n and at least a second birefringent layer with a third refractive index n2 and the second refractive index n.

18. The semiconductor component according to claim 5, wherein the chip-adjacent polarizing filter comprises a birefringent multilayer filter that comprises at least a first birefringent layer with a first refractive index n1 and a second refractive index n and at least a second birefringent layer with a third refractive index n2 and the second refractive index n.
